(19) United States
(12) Patent Application Publication
(10) Pub. No.: US 2025/0063702 A1
(43) Pub. Date: Feb. 20, 2025

(54) LIQUID COOLING SYSTEM FOR DATA CENTER AND CONTROL METHOD THEREOF

(71) Applicant: Hebei Qinhuai Data Co., Limited., Zhangjiakou City (CN)

(72) Inventors: Binghua ZHANG, Zhangjiakou City (CN); Yongbin LIU, Zhangjiakou City (CN)

(21) Appl. No.: 18/805,113

(22) Filed: Aug. 14, 2024

(30) Foreign Application Priority Data
Aug. 15, 2023 (CN) 202311026953.0

(51) Int. Cl. H05K 7/20

(52) U.S. Cl. CPC H05K 7/20827; H05K 7/20309; H05K 7/20318; H05K 7/20327; H05K 7/20836

(57) ABSTRACT

Embodiments of the present disclosure provide a liquid cooling system for a data center and a control method thereof, relating to the field of data center technology. The liquid cooling system includes an outdoor condenser, an indoor evaporator, a pressure sensor, a frequency converter, and a fluid transportation and distribution unit. The outdoor condenser and the indoor evaporator are connected through a pipeline to form a circuit. The pressure sensor, the frequency converter, and the fluid transportation and distribution unit are arranged on an outlet pipeline of the outdoor condenser.

### CROSS REFERENCE TO RELATED APPLICATION

This application claims priority to Chinese Patent Application No. 202311026953.0, titled “LIQUID COOLING SYSTEM FOR DATA CENTER AND CONTROL METHOD THEREOF” and filed to the China National Intellectual Property Administration on Aug. 15, 2023, the entire contents of which are incorporated herein by reference.

### TECHNICAL FIELD

The present disclosure relates to the field of data center technology, and more particularly, to a liquid cooling system for a data center and a control method thereof.

### BACKGROUND

Large-scale data centers typically use liquid cooling technologies to meet heat dissipation requirements for servers. At present, relatively low-cost and reliable liquid-cooled data centers typically use a cold plate liquid cooling system. The cold plate liquid cooling system is primarily comprised of a cooling tower, a coolant distribution unit (CDU), and a liquid-cooled cabinet.

In the above-mentioned cold plate liquid cooling system, transportation of primary side cooling water and secondary side liquid cooling coolant depends on a circulating water pump. Moreover, in conventional solutions, a two-stage heat exchange system is arranged, where heat from a server is transferred to the liquid cooling coolant by means of a cold plate. Next, the liquid cooling coolant exchanges heat with the cooling water by means of a heat exchange unit (also known as a heat interchange unit) of the CDU. Finally, the heat from the cooling water is dissipated outdoors by means of the cooling tower. This heat exchange process is relatively complicated.

### SUMMARY

To solve a technical problem of a relatively complex heat exchange process in the existing technology, embodiments of the present disclosure provide a liquid cooling system for a data center and a control method thereof, and the technical solutions are as follows.

In a first aspect, the present disclosure provides a liquid cooling system for a data center, including: an outdoor condenser, an indoor evaporator, a pressure sensor, a frequency converter, and a fluid transportation and distribution unit.

The outdoor condenser and the indoor evaporator are connected through a pipeline to form a circuit.

The pressure sensor, the frequency converter, and the fluid transportation and distribution unit are arranged on an outlet pipeline of the outdoor condenser.

Further, the fluid transportation and distribution unit includes a liquid reservoir and a liquid pump.

Further, a temperature sensor is arranged on the outlet pipeline of the outdoor condenser.

Further, a pressure sensor and a temperature sensor are arranged on an inlet pipeline of the outdoor condenser.

Further, an electronic expansion valve is arranged on an inlet pipeline of the indoor evaporator, and a temperature sensor is arranged on an outlet pipeline of the indoor evaporator.

Further, the indoor evaporator includes an evaporative liquid cooling cold plate, which is attached to a heating element of a server in the data center.

Further, a thermal conductive coating is provided between the heating element and the evaporative liquid cooling cold plate.

In a second aspect, the present disclosure provides a control method for a liquid cooling system, where the control method is applied to the liquid cooling system according to any one of the embodiments in the first aspect. The control method includes:
detecting a current outlet pressure of the outdoor condenser by means of a pressure sensor;
comparing the current outlet pressure with a preset operating condition to obtain a first pressure comparison result; and
determining whether to regulate a liquid supply pressure of the condenser by means of a frequency converter according to the first pressure comparison result.

Further, the control method also includes:
detecting a current outlet temperature of the outdoor condenser by means of a temperature sensor;
comparing the current outlet temperature with the preset operating condition to obtain a first temperature comparison result; and
determining whether to regulate power of the fluid transportation and distribution unit according to the first temperature comparison result.

Further, the control method also includes:
detecting a current inlet temperature of the indoor evaporator by means of a temperature sensor;
comparing the current inlet temperature with the preset operating condition to obtain a second temperature comparison result; and
determining whether to regulate liquid supply to the indoor evaporator by means of an electronic expansion valve according to the second temperature comparison result.

Further, the preset operating condition includes a preset temperature and a preset pressure.

Technical effects produced by the present disclosure are as below. In one aspect, the present disclosure adopts a dynamical heat pipe technology. The liquid cooling system of the present disclosure has a simple and compact structure, good heat transfer performance, and high reliability. Circulation of a refrigerant is achieved mainly by means of the dynamical heat pipe technology, which can overcome a problem that a distance of conveying the refrigerant is increased due to limitations on a height difference between the outdoor condenser and the indoor evaporator. In this way, deployment of internal and external machines is not limited by the height difference or distance. Moreover, compared to a conventional two-stage heat exchange system, the present disclosure reduces primary heat exchange, which further improves an energy utilization ratio of the cooling system for the data center. In another aspect, in the present disclosure, the current outlet pressure of the outdoor condenser is measured by means of the pressure sensor arranged on the outlet pipeline of the condenser, and an outlet pressure of the condenser, i.e. a liquid supply pressure, is controlled according to the pressure data. In this way, the liquid supply pressure can be controlled to maintain at a set operating condition, there ensuring smooth flow of the refrigerant in the pipeline, which is advantageous to heat dissipation from a server room to a natural cold source, thus improving utilization rate of the natural cold source.

### BRIEF DESCRIPTION OF THE DRAWINGS

To describe the technical solutions in the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a liquid cooling system for a data center according to an embodiment of the present disclosure;

FIG. 2 is a schematic structural diagram of a condenser according to an embodiment of the present disclosure; and

FIG. 3 is a pressure-enthalpy diagram of a dynamical heat pipe system according to an embodiment of the present disclosure.

### DETAILED DESCRIPTION

To make the objectives, technical solutions and advantages of the present disclosure clearer, the embodiments of the present disclosure are further described as below in details with reference to the accompanying drawings. The terms such as “upper”, “above”, “lower”, “below”, “first end”, “second end”, “one end”, “other end” as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, terms “installed”, “arranged”, “provided”, “connection”, “sliding connection”, “fixed”, and “sleeved” should be understood in a broad sense. For example, the “connection” may be a fixed connection, a detachable connection or integrated connection, a mechanical connection or an electrical connection, a direct connection or indirect connection by means of an intermediary, or internal connection between two apparatuses, elements, or components. The specific significations of the above terms in the present disclosure may be understood in the light of specific conditions by persons of ordinary skill in the art.

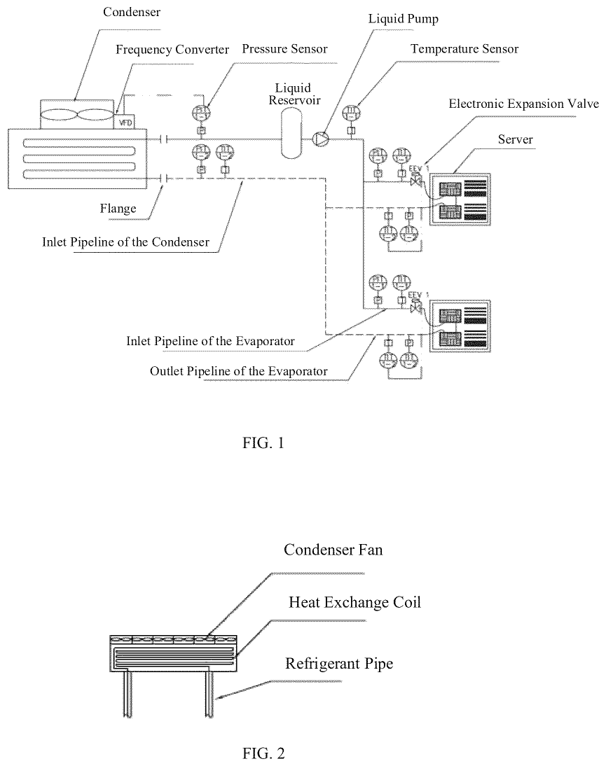

The embodiments of the present disclosure provide a liquid cooling system for a data center. As shown in FIG. 1, the liquid cooling system includes an outdoor condenser, an indoor evaporator, a pressure sensor, a frequency converter, and a fluid transportation and distribution unit. The outdoor condenser and the indoor evaporator are connected through a pipeline to form a circuit. The pressure sensor, the frequency converter, and the fluid transportation and distribution unit are arranged on an outlet pipeline of the outdoor condenser.

In FIG. 1, a line shown by a solid line may represent a water supply pipeline for a refrigerant; a line shown by a dotted line may represent a return water pipeline for the refrigerant; and a double dot dash line may represent a signal transduction circuit.

In implementation, an outlet pressure of the condenser can be controlled by means of the pressure sensor arranged on the outlet pipeline of the outdoor condenser. Specifically, a current outlet pressure of the outlet pipeline of the condenser is measured in real time by means of the pressure sensor. Next, the current outlet pressure is compared with the preset operating condition. When the current outlet pressure is lower, a liquid supply pressure of the condenser may be increased by means of the frequency converter. When the current outlet pressure is higher, the liquid supply pressure of the condenser may be decreased by means of the frequency converter.

Methods for adjusting the liquid supply pressure may include: adjusting revolution speed of the condenser fan of the condenser, adjusting number of the condenser fans of the condenser in operation, and adjusting a liquid supply flow of the outlet pipeline of the condenser, etc., but the present disclosure is not limited thereto.

In implementation, the condenser may be an air-cooled condenser such as a dry cooler, or an evaporative condenser such as a cooling tower. A fluid transportation and distribution unit is arranged on the outlet pipeline of the condenser in the present disclosure, which can provide power for circulation of a refrigerant. Principles of the circulation are as below. By taking advantage of transporting power provided by the fluid transportation and distribution unit, a refrigerant liquid flows through liquid pipelines such as the outlet pipeline of the condenser and an inlet pipeline of the evaporator in sequence. The refrigerant liquid absorbs heat from a heating element of a server in a computer room through the indoor evaporator and turns into a refrigerant gas. The refrigerant gas rises up through an outlet pipeline of the evaporator and an inlet pipeline of condenser and enters the outdoor condenser, where the refrigerant gas is cooled down by an outdoor natural cold source (such as air or water) and turns into a liquid. Next, the refrigerant liquid flows back through the liquid pipelines for evaporation, thereby forming a cooling cycle.

It is worth mentioning that the various pipelines in the present disclosure may be connected through flanges, or other connectors and connection modes may be used, but the present disclosure is not limited thereto.

In one embodiment, referring to FIG. 2, the condenser may include a condenser fan, a heat exchange coil, and a refrigerant pipe.

In implementation, the condenser fan is configured to provide power to outdoor air, such that the outdoor air flows through the outdoor condenser and takes away the heat released by the refrigerant in the heat exchange coil.

A water inlet end and a water outlet end of the heat exchange coil are connected to other pipelines by means of the refrigerant pipe, respectively.

In one embodiment, the fluid transportation and distribution unit may specifically include a liquid reservoir and a liquid pump.

In implementation, arrangement of the liquid reservoir can prevent cavitation erosion of the liquid pump and replenish supply of the refrigerant. Specifically, when an evaporation load of the evaporator increases, it is required to increase the supply of the refrigerant, which is replenished by a liquid stored in the liquid reservoir. When the evaporation load of the evaporator decreases, it is required to reduce the supply of the refrigerant, and excess refrigerant may be stored in the liquid reservoir.

Arrangement of the liquid pump can provide power for circulation of the refrigerant, and by replacing a conventional water pump with a dynamical heat pipe technology to transport the refrigerant, an annual Power Usage Efficiency (PUE) of the liquid cooling system is reduced from 1.13 (air conditioning factor is 0.08, and power factor is 0.05) to 1.095 (the air conditioning factor is 0.045, and the power factor is 0.05).

In one embodiment, due to higher outlet temperature of the liquid cooling system, an annual Cooling Load Factor (CLF) of the liquid cooling system generally may be reduced by more than 50% in various scenarios.

In one embodiment, the fluid transportation and distribution unit uses a fluorine pump instead of the conventional water pump. Because the refrigerant uses phase change refrigeration and the refrigerant has a greater latent heat of vaporization, a required flow rate of the refrigerant is much smaller than that of single-phase heat exchange, such that pumping energy consumption is about ⅛ of that of the conventional water pump system.

In one embodiment, a temperature sensor may also be arranged on the outlet pipeline of the outdoor condenser.

In implementation, temperature of the refrigerant in the outlet pipeline of the outdoor condenser may be measured by means of the temperature sensor, and frequency conversion of the fluorine pump is controlled according to the temperature data, thereby adjusting the supply of the refrigerant and improving heat exchange efficiency.

In another embodiment, a pressure sensor and a temperature sensor are also arranged on an inlet pipeline of the outdoor condenser.

In implementation, pressure and temperature of the refrigerant in the inlet pipeline of the outdoor condenser may also be measured by means of the pressure sensor and the temperature sensor. In this way, it is easier to calculate hydraulic pressure and temperature differences between the water supply pipeline and the return water pipeline for the refrigerant. Further, it facilitates real-time calculation of demands for refrigeration of the liquid cooling system, and operating states of various components in the system is regulated on the basis of the demands for refrigeration, thereby achieving a better energy efficiency ratio.

In one embodiment, an electronic expansion valve may be arranged on the inlet pipeline of the indoor evaporator, and the temperature sensor may be arranged on the outlet pipeline of the indoor evaporator.

In implementation, the temperature of the refrigerant in the outlet pipeline of the indoor evaporator may be measured by means of the temperature sensor, and opening degree of the electronic expansion valve may be regulated on the basis of the temperature data to achieve the objective of regulating the supply of the refrigerant, thereby ensuring sufficient heat dissipation of the server. For example, when the temperature of the refrigerant in the outlet pipeline of the indoor evaporator is too high compared to the preset operating condition, it indicates to some extent that the supply of the refrigerant is not sufficient. In this case, the opening degree of the electronic expansion valve may be increased to increase the supply of the refrigerant. However, when the temperature of the refrigerant in the outlet pipeline of the indoor evaporator is too low compared to the preset operating condition, it indicates to some extent that the supply of the refrigerant is excessive. In this case, the opening degree of the electronic expansion valve may be decreased to reduce the supply of the refrigerant.

It is worth mentioning that the refrigerant may use R134a (that is, 1,1,1,2-tetrafluoroethane, whose chemical formula is C₂H₂F₄) as an environmentally friendly refrigerant, or other refrigerants may also be used, but the present disclosure is not limited thereto.

In one embodiment, the indoor evaporator includes an evaporative liquid cooling cold plate, which is attached to the heating element of the server in the data center.

In implementation, attachment of the evaporative liquid cooling cold plate to the heating element of the server in the data center can accelerate heat exchange and improve refrigeration efficiency. The use of the evaporative liquid cooling cold plate significantly increases a heat dissipation upper limit of power consumption of a single chip, such that heat dissipation capability of the single chip approaches the upper limit (700-900 W) under single-phase coolant technology conditions. Thus, the evaporative liquid cooling cold plate can greatly improve the heat dissipation capability of the single chip and assist in iteration of chip heat dissipation technologies.

In one embodiment, a thermal conductive coating is provided between the heating element and the evaporative liquid cooling cold plate.

In implementation, the heating element may be a CPU (Central Processing Unit) chip or GPU (Graphics Processing Unit) chip of the server. The thermal conductive coating may use a metal-based material such as metal-based graphene composite coating, or may use a non-metallic-based material such as non-metallic-based silicone grease or organic resin. A method for spraying the thermal conductive coating may be cold spraying, supersonic plasma spraying, or thermal spraying, etc., but the present disclosure is not limited thereto.

In one embodiment, the liquid cooling system may also include a flow distribution unit, which may include a coolant distribution unit, a hose, a quick coupler, and a refrigerant pipe. The refrigerant pipe is connected to the outdoor condenser, and the hose is connected to the evaporative liquid cooling cold plate of the indoor evaporator by means of the quick coupler. A water inlet end and a water outlet end of a cold plate of the server are connected to the hose by means of a quick coupler, respectively. The quick coupler can ensure that the server has online plug maintenance performance.

In implementation, the coolant distribution unit may be a manifold configured to connect water inlet and outlet pipelines of various liquid cooling cold plates. A connection method of the hose may be vertebral tube buckle type or clamp-on design, or other connection methods may also be used, but the present disclosure is not limited thereto.

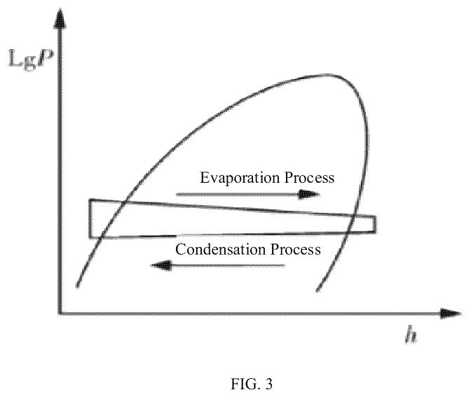

FIG. 3 is a pressure-enthalpy diagram of a dynamical heat pipe system according to an embodiment of the present disclosure. The vertical axis lg P represents a logarithmic value of the pressure, and the horizontal axis H represents an enthalpy value. In the present disclosure, the refrigerant mainly relies on a driving force from the liquid pump to circulate and flow. The liquid pump increases pressure of the evaporator, causing condensation temperature to be lower than evaporation temperature. Rise in the condensation temperature is more conducive to the heat dissipation from a loop heat pipe to the natural cold source, thereby improving utilization rate of the natural cold source of the loop heat pipe.

In one embodiment, the outlet pipeline and the inlet pipeline of the indoor evaporator may also be provided with other valves such as an expansion valve, a shut-off valve, or a solenoid valve, but the present disclosure is not limited thereto.

The liquid cooling system may include a plurality of sets of evaporators to dissipate heat from different servers. The outlet pipeline of each evaporator converges into the inlet pipeline of the condenser, and the outlet pipeline of the condenser is divided into a plurality of branches, which are connected to the inlet pipeline of each evaporator. The inlet pipeline and the outlet pipeline of the evaporator may be independently opened/closed and regulated by means of the valve. In this way, a cooling range or refrigerating capacity of the system can be independently controlled. For example, when a certain server is no longer in use, the liquid cooling system may be controlled to no longer supply the refrigerant to the server by closing the valves on the inlet and outlet pipelines of the evaporator.

Technical effects produced by the above embodiments are as below. In one aspect, the present disclosure adopts a dynamical heat pipe technology. The liquid cooling system of the present disclosure has a simple and compact structure, good heat transfer performance, and high reliability. Circulation of the refrigerant is achieved by means of the dynamical heat pipe technology, which can overcome a problem that a distance of conveying the refrigerant is increased due to limitations on a height difference between the outdoor condenser and the indoor evaporator. In this way, deployment of internal and external machines is not limited by the height difference or distance. Moreover, compared to a conventional two-stage heat exchange system, the present disclosure reduces primary heat exchange, which further improves an energy utilization ratio of the cooling system for the data center. In another aspect, in the present disclosure, the current outlet pressure of the outdoor condenser is measured by means of the pressure sensor arranged on the outlet pipeline of the condenser, and an outlet pressure of the condenser, i.e. a liquid supply pressure, is controlled according to the pressure data. In this way, the liquid supply pressure can be controlled to maintain at a set operating condition, there ensuring smooth flow of the refrigerant in the pipeline, which is advantageous to heat dissipation from a server room to a natural cold source, thus improving utilization rate of the natural cold source.

Based on the same inventive concept, the present disclosure also provides a control method for a liquid cooling system, where the control method is applied to the liquid cooling system described in any one the above embodiments. The control method includes:
detecting a current outlet pressure of the outdoor condenser by means of a pressure sensor;
comparing the current outlet pressure with a preset operating condition to obtain a first pressure comparison result; and
determining whether to regulate a liquid supply pressure of the condenser by means of a frequency converter according to the first pressure comparison result.

In one embodiment, the control method also includes:
detecting a current outlet temperature of the outdoor condenser by means of a temperature sensor;
comparing the current outlet temperature with the preset operating condition to obtain a first temperature comparison result; and
determining whether to regulate power of the fluid transportation and distribution unit according to the first temperature comparison result.

In one embodiment, the control method also includes:
detecting a current inlet temperature of the indoor evaporator by means of a temperature sensor;
comparing the current inlet temperature with the preset operating condition to obtain a second temperature comparison result; and
determining whether to regulate supply of the refrigerant to the indoor evaporator by means of an electronic expansion valve according to the second temperature comparison result.

In one embodiment, the preset operating condition includes a preset temperature and a preset pressure.

The foregoing descriptions are merely preferred embodiments of the present disclosure, and are not intended to limit the present disclosure. Any modification, equivalent replacement and improvement made within the spirit and principle of the present disclosure shall fall into the protection scope of the present disclosure.

What is claimed is:

1. A liquid cooling system for a data center, comprising an outdoor condenser, an indoor evaporator, a pressure sensor, a frequency converter, and a fluid transportation and distribution unit; wherein
the outdoor condenser and the indoor evaporator are connected through a pipeline to form a circuit; and
the pressure sensor, the frequency converter, and the fluid transportation and distribution unit are arranged on an outlet pipeline of the outdoor condenser.

2. The liquid cooling system as claimed in claim 1, wherein the fluid transportation and distribution unit comprises a liquid reservoir and a liquid pump.

3. The liquid cooling system as claimed in claim 1, wherein a temperature sensor is arranged on the outlet pipeline of the outdoor condenser.

4. The liquid cooling system as claimed in claim 3, wherein a pressure sensor and the temperature sensor are arranged on an inlet pipeline of the outdoor condenser.

5. The liquid cooling system as claimed in claim 1, wherein an electronic expansion valve is arranged on an inlet pipeline of the indoor evaporator, and a temperature sensor is arranged on an outlet pipeline of the indoor evaporator.

6. The liquid cooling system as claimed in claim 1, wherein the indoor evaporator comprises an evaporative liquid cooling cold plate attached to a heating element of a server in the data center.

7. The liquid cooling system as claimed in claim 6, wherein a thermal conductive coating is provided between the heating element and the evaporative liquid cooling cold plate.

8. A control method for a liquid cooling system, wherein the control method is applied to a liquid cooling system comprising an outdoor condenser, an indoor evaporator, a pressure sensor, a frequency converter, and a fluid transportation and distribution unit, the control method comprising:
detecting a current outlet pressure of the outdoor condenser by means of a pressure sensor;
comparing the current outlet pressure with a preset operating condition to obtain a first pressure comparison result; and
determining whether to regulate a liquid supply pressure of the condenser by means of a frequency converter according to the first pressure comparison result.

9. The control method for the liquid cooling system as claimed in claim 8 further comprising:
detecting a current outlet temperature of the outdoor condenser by means of a temperature sensor;
comparing the current outlet temperature with the preset operating condition to obtain a first temperature comparison result; and
determining whether to regulate power of the fluid transportation and distribution unit according to the first temperature comparison result.

10. The control method for the liquid cooling system as claimed in claim 8 further comprising:
detecting a current inlet temperature of the indoor evaporator by means of a temperature sensor;
comparing the current inlet temperature with the preset operating condition to obtain a second temperature comparison result; and
determining whether to regulate liquid supply to the indoor evaporator by means of an electronic expansion valve according to the second temperature comparison result.

11. The control method for the liquid cooling system as claimed in claim 8, wherein the preset operating condition comprises a preset temperature and a preset pressure.
